(19) United States
(12) Patent Application Publication
(10) Pub. No.: US 2026/0164644 A1
(43) Pub. Date: Jun. 11, 2026

(54) SEMICONDUCTOR WAFER AND METHOD OF MANUFACTURING SEMICONDUCTOR DEVICE

(71) Applicant: Renesas Electronics Corporation, Tokyo (JP)

(72) Inventors: Hiraku CHAKIHARA, Tokyo (JP); Yoshiyuki KAWASHIMA, Tokyo (JP)

(21) Appl. No.: 19/371,020

(22) Filed: Oct. 28, 2025

(30) Foreign Application Priority Data
Dec. 11, 2024 (JP) 2024-217057

(51) Int. Cl. H10B 12/00; H10B 10/00

(52) U.S. Cl. CPC H10B 12/485; H10B 10/12; H10B 12/05

(57) ABSTRACT

A semiconductor wafer includes a semiconductor substrate, a plurality of chip regions, a scribe region, and an interlayer insulating film. A TEG is formed in the scribe region. The TEG includes a first active region formed in the semiconductor substrate, a second active region formed in the semiconductor substrate, and adjacent to the first active region in a first direction, a gate electrode formed on the first active region and the second active region, and extending in the first direction, an insulating region adjacent to the second active region in a second direction orthogonal to the first direction, and formed in the semiconductor substrate so as not to overlap with the first gate electrode in plan view, a plug formed in the interlayer insulating film and connected to the first active region, and a dummy plug formed in the interlayer insulating film and connected to the insulating region.

### CROSS-REFERENCE TO RELATED APPLICATIONS

The disclosure of Japanese Patent Application No. 2024-217057 filed on Dec. 11, 2024 including the specification, drawings and abstract is incorporated herein by reference in its entirety.

### BACKGROUND

The present invention relates to a semiconductor wafer and a method of manufacturing a semiconductor device, and more particularly to a technique that is effective when applied to a semiconductor wafer including, for example, a Test Element Group (TEG).

There are disclosed techniques listed below.

[Patent Document 1] Japanese Unexamined Patent Application Publication No.2007-19342

Patent Document 1 discloses a technique related to a TEG for detecting piping defects that occur between contact plugs.

### SUMMARY

For example, in order to advance the miniaturization of semiconductor devices, reducing the spacing between adjacent cells has been considered. In a manufacturing process of a semiconductor device, an interlayer insulating film is formed so as to cover a plurality of cells. When the spacing between adjacent cells becomes narrower, the aspect ratio between the gate electrodes of the cells increases. As a result, it becomes difficult to sufficiently embed the interlayer insulating film between the gate electrodes of the cells. Consequently, voids may be generated in the interlayer insulating film embedded between the gate electrodes of the cells.

A plurality of plugs is formed in the interlayer insulating film. When voids are generated in the interlayer insulating film, a conductive material of the plurality of plugs may be embedded into the voids. As a result, adjacent plugs may become conductive through the conductive material embedded in the voids, potentially causing a piping defect.

In this regard, there is a method of detecting a piping defect by performing a wafer test after forming cells and wirings on a wafer. In order to detect a piping defect based on the wafer test, it is necessary to perform physical analysis after detecting an abnormality in the wafer test and identify the piping defect. In this case, it takes time to detect the piping defect.

Accordingly, it is desired that a piping defect be accurately detected at an early stage of the manufacturing process of a semiconductor device.

Other objects and novel features will become apparent from the description of this specification and the accompanying drawings.

According to one embodiment, a semiconductor wafer includes a semiconductor substrate, a plurality of chip regions, a scribe region that partitions the plurality of chip regions, and an interlayer insulating film formed on the semiconductor substrate. A TEG is formed in the scribe region. The TEG includes a first active region formed in the semiconductor substrate, a second active region formed in the semiconductor substrate, and adjacent to the first active region in a first direction, a first gate electrode formed on the first active region and the second active region, and extending in the first direction, an insulating region adjacent to the second active region in a second direction orthogonal to the first direction, and formed in the semiconductor substrate so as not to overlap with the first gate electrode in plan view, a first plug formed in the interlayer insulating film and connected to the first active region, and a second plug formed in the interlayer insulating film and connected to the insulating region.

According to one embodiment, a method of manufacturing a semiconductor device, comprising the steps of (a) preparing a semiconductor wafer having a semiconductor substrate, a plurality of chip regions, a scribe region that partitions the plurality of chip regions, an interlayer insulating film formed on the semiconductor substrate, and a TEG formed in the scribe region, and (b) detecting a piping defect between a first plug and a second plug. The TEG includes a first active region formed in the semiconductor substrate, a second active region formed in the semiconductor substrate, and adjacent to the first active region in a first direction, a first gate electrode formed on the first active region and the second active region, and extending in the first direction, an insulating region adjacent to the second active region in a second direction orthogonal to the first direction, and formed in the semiconductor substrate so as not to overlap with the first gate electrode in plan view, a first plug formed in the interlayer insulating film and connected to the first active region, and a second plug formed in the interlayer insulating film and connected to the insulating region.

According to one embodiment, a piping defect can be accurately detected at an early stage of a manufacturing process of a semiconductor device.

### BRIEF DESCRIPTION OF THE DRAWINGS

FIG. 1 is a diagram illustrating a layout of a non-volatile memory formed in a chip region.

FIG. 2 is a cross-sectional view of the non-volatile memory taken along line A-A in FIG. 1.

FIG. 3 is a diagram illustrating a layout of a TEG in a first related technique.

FIG. 4 is a diagram illustrating a layout of a TEG in a second related technique.

FIG. 5 is a diagram illustrating a basic concept.

FIG. 6 is a diagram illustrating a layout of a TEG in a first embodiment.

FIG. 7 is a cross-sectional view of the TEG taken along line A-A in FIG. 6.

FIG. 8 is a diagram illustrating the layout of the TEG in the first embodiment in a state where no piping defect is present.

FIG. 8 is a diagram illustrating a layout of the TEG in the first embodiment in a state where a piping defect is present.

FIG. 10 is a diagram illustrating a layout of a TEG in a second embodiment in a state where no piping defect is present.

FIG. 11 is a diagram illustrating a layout of the TEG in the second embodiment in a state where a piping defect is present. FIG. 12 is a diagram illustrating a conduction check in an examination example.

FIG. 13 is a diagram illustrating a conduction check in the second embodiment.

FIG. 14 is a diagram illustrating a layout of a TEG in a third embodiment in a state where no piping defect is present.

FIG. 15 is a diagram illustrating the layout of the TEG in the third embodiment in a state where a piping defect is present.

FIG. 16 is a diagram illustrating a layout of a TEG in the examination example.

FIG. 17 is a diagram illustrating a layout of a TEG in a fourth embodiment.

### DETAILED DESCRIPTION

In all the drawings for explaining the embodiments, the same reference numerals are basically assigned to the same components, and repeated explanations thereof are omitted. It should be noted that, for the sake of clarity, hatching may be applied even in plan views.

### Examination of Improvement

A semiconductor wafer has a plurality of chip regions and a scribe region that partitions the plurality of chip regions. In each of the plurality of chip regions, a semiconductor device used as a product is formed. Whereas, the scribe region is cut by a dicing saw during a dicing process in which the semiconductor wafer is divided into a plurality of semiconductor chips.

In general, a TEG is often formed in a scribe region. TEG is a test pattern formed in a scribe region of a semiconductor wafer to evaluate a semiconductor process or device. Using the TEG, characteristics of circuit patterns are evaluated, and defects and the like that occur during the manufacturing of a semiconductor device are evaluated or analyzed.

For example, the use of a TEG has been considered to detect the presence or absence of a piping defect. The following describes related techniques that detects a piping defect using the TEG.

In the present specification, the term “related technique” refers to a technique that is not a publicly known technique but has problems identified by the present inventor, and serves as a premise for the present disclosure.

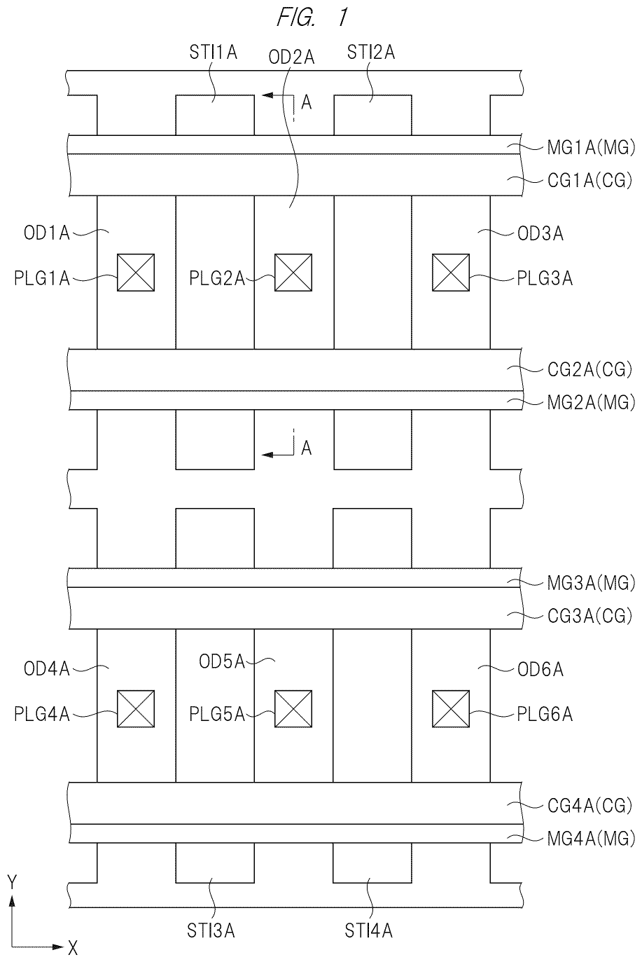

FIG. 1 is a diagram illustrating a layout of a non-volatile memory formed in a chip region.

In FIG. 1, the non-volatile memory includes a control gate electrode CG1A, a control gate electrode CG2A, a control gate electrode CG3A, a control gate electrode CG4A, a memory gate electrode MG1A, a memory gate electrode MG2A, a memory gate electrode MG3A, a memory gate electrode MG4A, an active region OD1A, an active region OD2A, an active region OD3A, an active region OD4A, an active region OD5A, an active region OD6A, an insulating region STI1A, an insulating region STI2A, an insulating region STI3A, an insulating region STI4A, a plug PLG1A, a plug PLG2A, a plug PLG3A, a plug PLG4A, a plug PLG5A, and a plug PLG6A.

The control gate electrode CG1A and the memory gate electrode MG1A extend in an X direction in parallel with each other. The control gate electrode CG2A and the memory gate electrode MG2A extend in the X direction in parallel with each other. The control gate electrode CG3A and the memory gate electrode MG3A extend in the X direction in parallel with each other. The control gate electrode CG4A and the memory gate electrode MG4A extend in the X direction in parallel with each other.

The active region OD1A has portions that overlap with the control gate electrode CG1A and the control gate electrode CG2A in plan view. The active region OD2A has portions that overlap with the control gate electrode CG1A and the control gate electrode CG2A in plan view. The active region OD3A has portions that overlap with the control gate electrode CG1A and the control gate electrode CG2A in plan view.

The active region OD4A has portions that overlap with the control gate electrode CG3A and the control gate electrode CG4A in plan view. The active region OD5A has portions that overlap with the control gate electrode CG3A and the control gate electrode CG4A in plan view. The active region OD6A has portions that overlap with the control gate electrode CG3A and the control gate electrode CG4A in plan view.

The insulating region STI1A extends in a Y direction. The insulating region STI1A is located, in plan view, between the active region OD1A and the active region OD2A. The insulating region STI1A includes portions that overlap with the control gate electrode CG1A and the memory gate electrode MG1A in plan view. The insulating region STI1A includes portions that overlap with the control gate electrode CG2A and the memory gate electrode MG2A in plan view.

The insulating region STI2A extends in the Y direction. The insulating region STI2A is located, in plan view, between the active region OD2A and the active region OD3A. The insulating region STI2A includes portions that overlap with the control gate electrode CG1A and the memory gate electrode MG1A in plan view. The insulating region STI2A includes portions that overlap with the control gate electrode CG2A and the memory gate electrode MG2A in plan view.

The insulating region STI3A extends in the Y direction. The insulating region STI3A is located, in plan view, between the active region OD1A and the active region OD2A. The insulating region STI3A includes portions that overlap with the control gate electrode CG3A and the memory gate electrode MG3A in plan view. The insulating region STI3A includes portions that overlap with the control gate electrode CG4A and the memory gate electrode MG4A in plan view.

The insulating region STI4A extends in the Y direction. The insulating region STI4A is located, in plan view, between the active region OD2A and the active region OD3A. The insulating region STI4A includes portions that overlap with the control gate electrode CG3A and the memory gate electrode MG3A in plan view. The insulating region STI4A includes portions that overlap with the control gate electrode CG4A and the memory gate electrode MG4A in plan view.

The plug PLG1A is located, in plan view, between the control gate electrode CG1A and the control gate electrode CG2A. The plug PLG1A is formed on the active region OD1A. The plug PLG1A is electrically connected to the active region OD1A.

The plug PLG2A is located, in plan view, between the control gate electrode CG1A and the control gate electrode CG2A. The plug PLG2A is formed on the active region OD2A. The plug PLG2A is electrically connected to the active region OD2A.

The plug PLG3A is located, in plan view, between the control gate electrode CG1A and the control gate electrode CG2A. The plug PLG3A is formed on the active region OD3A. The plug PLG3A is electrically connected to the active region OD3A.

The plug PLG4A is located, in plan view, between the control gate electrode CG3A and the control gate electrode CG4A. The plug PLG4A is formed on the active region OD4A. The plug PLG4A is electrically connected to the active region OD4A.

The plug PLG5A is located, in plan view, between the control gate electrode CG3A and the control gate electrode CG4A. The plug PLG5A is formed on the active region OD5A. The plug PLG5A is electrically connected to the active region OD5A.

The plug PLG6A is located, in plan view, between the control gate electrode CG3A and the control gate electrode CG4A. The plug PLG6A is formed on the active region OD6A. The plug PLG6A is electrically connected to the active region OD6A.

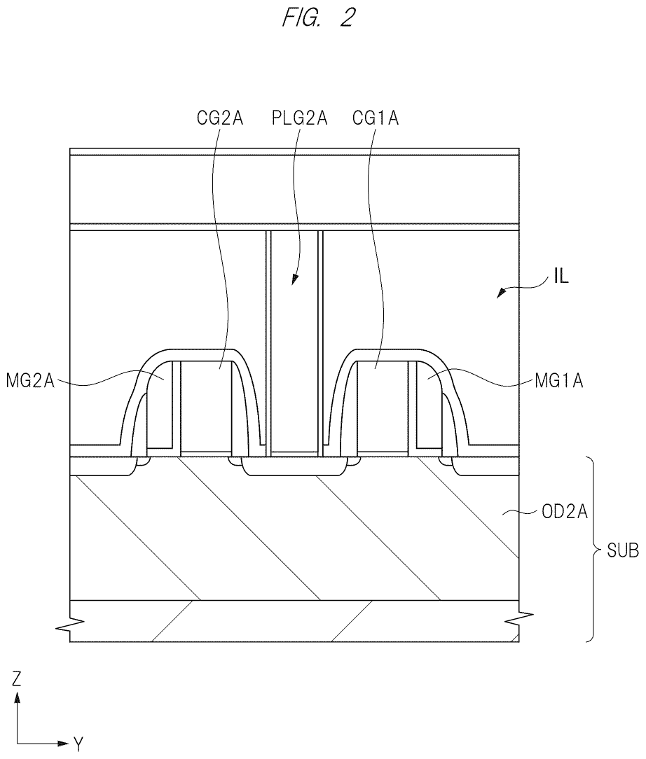

FIG. 2 is a cross-sectional view of the non-volatile memory taken along line A-A in FIG. 1.

In FIG. 2, the active region OD2A is formed in a semiconductor substrate SUB. On the active region OD2A, the control gate electrode CG1A is formed via a gate insulating film. On the active region OD2A, the control gate electrode CG2A is also formed via the gate insulating film. In the Y direction, the control gate electrode CG1A and the control gate electrode CG2A are spaced apart from each other.

On one sidewall of the control gate electrode CG1A, the memory gate electrode MG1A is formed via a stacked insulating film (ONO film). On one sidewall of the control gate electrode CG2A, the memory gate electrode MG2A is formed via the stacked insulating film (an ONO film). An interlayer insulating film IL is formed on the active region OD2A so as to cover the control gate electrode CG1A, the memory gate electrode MG1A, the control gate electrode CG2A, and the memory gate electrode MG2A. The plug PLG2A is formed in the interlayer insulating film IL. The plug PLG2A is connected to a drain region. The plug PLG2A is located, in the Y direction, between the control gate electrode CG1A and the control gate electrode CG2A.

In the non-volatile memory configured as described above, for example, a piping defect may occur between the plug PLG1A and the plug PLG2A. In order to detect the piping defect, a first related technique is considered in which a TEG is used to detect the piping defect.

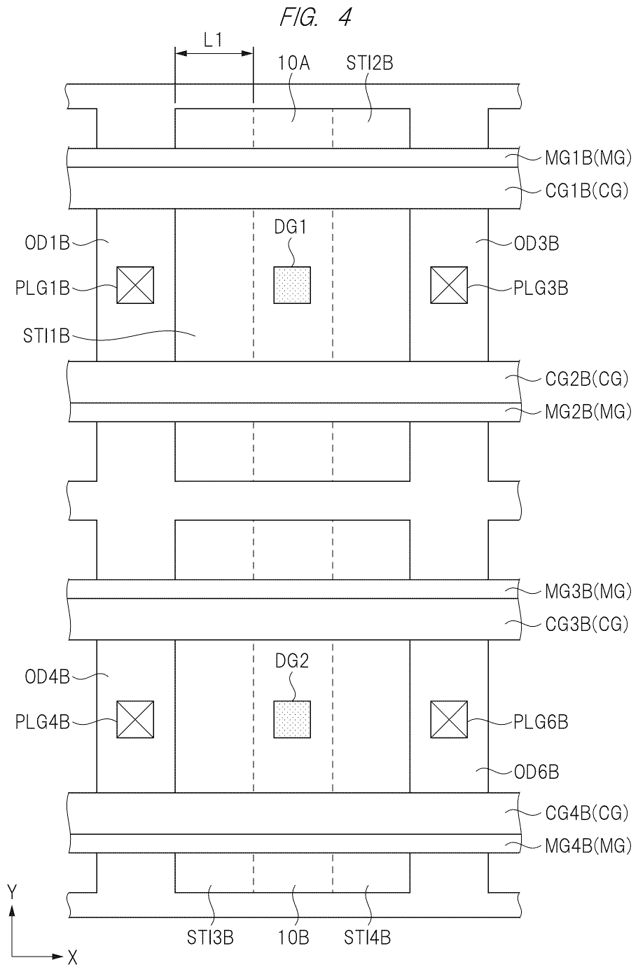

FIG. 4 is a diagram illustrating a layout of a TEG in the first related technique.

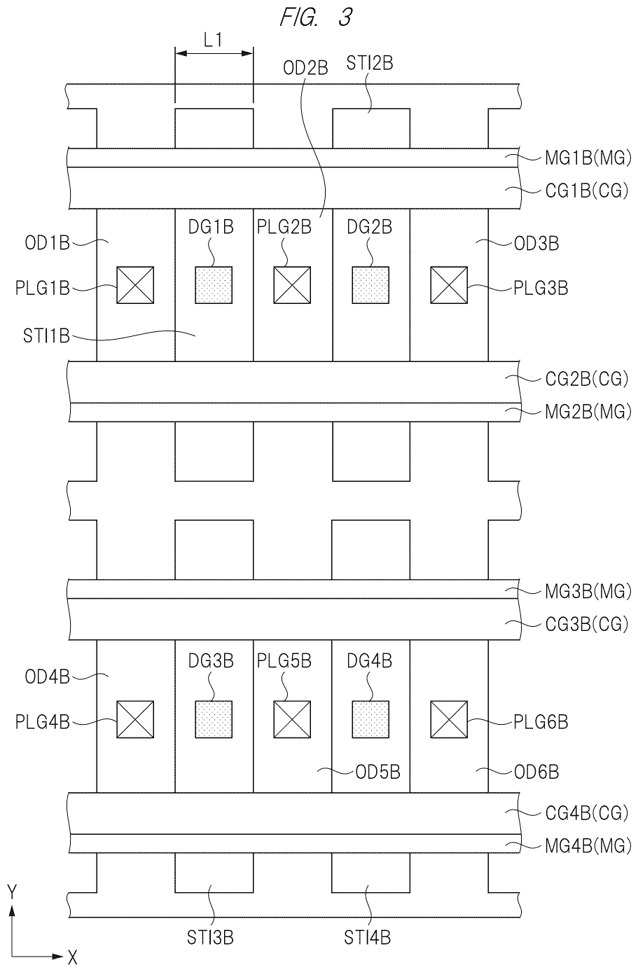

In FIG. 3, the TEG includes a control gate electrode CG1B, a control gate electrode CG2B, a control gate electrode CG3B, a control gate electrode CG4B, a memory gate electrode MG1B, a memory gate electrode MG2B, a memory gate electrode MG3B, a memory gate electrode MG4B, an active region OD1B, an active region OD2B, an active region OD3B, an active region OD4B, an active region OD5B, an active region OD6B, an insulating region STI1B, an insulating region STI2B, an insulating region STI3B, an insulating region STI4B, a plug PLG1B, a plug PLG2B, a plug PLG3B, a plug PLG4B, a plug PLG5B, a plug PLG6B, a dummy plug DG1B, a dummy plug DG2B, a dummy plug DG3B, and a dummy plug DG4B.

The control gate electrode CG1B and the memory gate electrode MG1B extend in the X direction in parallel with each other. The control gate electrode CG2B and the memory gate electrode MG2B extend in the X direction in parallel with each other. The control gate electrode CG3B and the memory gate electrode MG3B extend in the X direction in parallel with each other. The control gate electrode CG4B and the memory gate electrode MG4B extend in the X direction in parallel with each other.

The active region OD1B has portions that overlap with the control gate electrode CG1B and the control gate electrode CG2B in plan view. The active region OD2B has portions that overlap with the control gate electrode CG1B and the control gate electrode CG2B in plan view. The active region OD3B has portions that overlap with the control gate electrode CG1B and the control gate electrode CG2B in plan view.

The active region OD4B has portions that overlap with the control gate electrode CG3B and the control gate electrode CG4B in plan view. The active region OD5B has portions that overlap with the control gate electrode CG3B and the control gate electrode CG4B in plan view. The active region OD6B has portions that overlap with the control gate electrode CG3B and the control gate electrode CG4B in plan view.

The insulating region STI1B extends in the Y direction. The insulating region STI1B is located, in plan view, between the active region OD1B and the active region OD2B. The insulating region STI1B includes portions that overlap with the control gate electrode CG1B and the memory gate electrode MG1B in plan view. The insulating region STI1B includes portions that overlap with the control gate electrode CG2B and the memory gate electrode MG2B in plan view.

The insulating region STI2B extends in the Y direction. The insulating region STI2B is located, in plan view, between the active region OD2B and the active region OD3B. The insulating region STI2B includes portions that overlap with the control gate electrode CG1B and the memory gate electrode MG1B in plan view. The insulating region STI2B includes portion that overlap with the control gate electrode CG2B and the memory gate electrode MG2B in plan view.

The insulating region STI3B extends in the Y direction. The insulating region STI3B is located, in plan view, between the active region OD1B and the active region OD2B. The insulating region STI3B includes portions that overlap with the control gate electrode CG3B and the memory gate electrode MG3B in plan view. The insulating region STI3B includes portions that overlap with the control gate electrode CG4B and the memory gate electrode MG4B in plan view.

The insulating region STI4B extends in the Y direction. The insulating region STI4B is located, in plan view, between the active region OD2B and the active region OD3B. The insulating region STI4B includes portions that overlap with the control gate electrode CG3B and the memory gate electrode MG3B in plan view. The insulating region STI4B includes portions that overlap with the control gate electrode CG4B and the memory gate electrode MG4B in plan view.

The plug PLG1B is located, in plan view, between the control gate electrode CG1B and the control gate electrode CG2B. The plug PLG1B is formed on the active region OD1B. The plug PLG1B is electrically connected to the active region OD1B.

The plug PLG2B is located, in plan view, between the control gate electrode CG1B and the control gate electrode CG2B. The plug PLG2B is formed on the active region OD2B. The plug PLG2B is electrically connected to the active region OD2B.

The plug PLG3B is located, in plan view, between the control gate electrode CG1B and the control gate electrode CG2B. The plug PLG3B is formed on the active region OD3B. The plug PLG3B is electrically connected to the active region OD3B.

The plug PLG4B is located, in plan view, between the control gate electrode CG3B and the control gate electrode CG4B. The plug PLG4B is formed on the active region OD4B. The plug PLG4B is electrically connected to the active region OD4B.

The plug PLG5B is located, in plan view, between the control gate electrode CG3B and the control gate electrode CG4B. The plug PLG5B is formed on the active region OD5B. The plug PLG5B is electrically connected to the active region OD5B.

The plug PLG6B is located, in plan view, between the control gate electrode CG3B and the control gate electrode CG4B. The plug PLG6B is formed on the active region OD6B. The plug PLG6B is electrically connected to the active region OD6B.

The dummy plug DG1B is located, in plan view, between the control gate electrode CG1B and the control gate electrode CG2B. The dummy plug DG1B is located, in plan view, between the active region OD1B and the active region OD2B. The dummy plug DG1B is located, in plan view, between the plug PLG1B and the plug PLG2B. The dummy plug DG1B is formed on the insulating region STI1B.

The dummy plug DG2B is located, in plan view, between the control gate electrode CG1B and the control gate electrode CG2B. The dummy plug DG2B is located, in plan view, between the active region OD2B and the active region OD3B. The dummy plug DG2B is located, in plan view, between the plug PLG2B and the plug PLG3B. The dummy plug DG2B is formed on the insulating region STI2B.

The dummy plug DG3B is located, in plan view, between the control gate electrode CG3B and the control gate electrode CG4B. The dummy plug DG3B is located, in plan view, between the active region OD1B and the active region OD2B. The dummy plug DG3B is located, in plan view, between the plug PLG4B and the plug PLG5B. The dummy plug DG3B is formed on the insulating region STI3B.

The dummy plug DG4B is located, in plan view, between the control gate electrode CG3B and the control gate electrode CG4B. The dummy plug DG4B is located, in plan view, between the active region OD2B and the active region OD3B. The dummy plug DG4B is located, in plan view, between the plug PLG5B and the plug PLG6B. The dummy plug DG4B is formed on the insulating region STI4B.

In the TEG configured as described above, for example, in FIG. 3, when a piping defect occurs between the plug PLG1B and the plug PLG2B, the dummy plug DG1B, which is located between the plug PLG1B and the plug PLG2B, is also electrically connected to the plug PLG1B and the plug PLG2B.

On the other hand, when no piping defect occurs between the plug PLG1B and the plug PLG2B, the dummy plug DG1B, which is located between the plug PLG1B and the plug PLG2B, is electrically isolated from the plug PLG1B and the plug PLG2B.

Accordingly, a piping defect can be detected, for example, by inspecting whether conduction or non-conduction occurs between the plug PLG1B and the dummy plug DG1B. The conduction or non-conduction between the plug PLG1B and the dummy plug DG1B can be detected by a potential contrast method, which will be described later. When a piping defect is detected in the TEG formed in a scribe region, there is a high probability that a piping defect has also occurred in the non-volatile memory formed in a chip region. Therefore, a piping defect in the non-volatile memory can be detected by using the TEG.

Accordingly, the TEG in the first related technique can detect a piping defect. However, in recent years, the miniaturization of semiconductor devices has been advancing, and, for example, the layout of the non-volatile memory illustrated in FIG. 1 is being scaled down. In this case, in the TEG illustrated in FIG. 3, the width L1 in the X direction of the insulating region STI1B illustrated in FIG. 3 is also reduced, for example. As a result, it becomes difficult to form the dummy plug DG1B on the insulating region STI1B. Accordingly, as the miniaturization of semiconductor devices progresses, it becomes difficult to use the TEG illustrated in FIG. 3.

In this regard, a TEG in a second related technique has been considered.

FIG. 4 is a diagram illustrating the layout of a TEG in the second related technique.

In FIG. 4, the active region OD2B and the active region OD5B illustrated in FIG. 3 are not formed. In the second related technique illustrated in FIG. 4, an insulating region 10A and an insulating region 10B, which are indicated by dotted lines, are formed. The dummy plug DG1 is formed on the insulating region 10A.

The dummy plug DG1 is located, in plan view, between the control gate electrode CG1 and the control gate electrode CG2. The dummy plug DG1 is located, in plan view, between the active region OD1B and the active region OD3B. The dummy plug DG1 is located, in plan view, between the plug PLG1B and the plug PLG3B.

The dummy plug DG2 is formed on the insulating region 10B. The dummy plug DG2 is located, in plan view, between the control gate electrode CG3 and the control gate electrode CG4. The dummy plug DG2 is located, in plan view, between the active region OD1B and the active region OD3B. The dummy plug DG2 is located, in plan view, between the plug PLG4B and the plug PLG6B.

In the TEG configured as described above, for example, in FIG. 4, when a piping defect occurs between the plug PLG1B and the dummy plug DG1, the plug PLG1B and the dummy plug DG1 become electrically connected. In contrast, when no piping defect occurs between the plug PLG1B and the dummy plug DG1, the plug PLG1B and the dummy plug DG1 are electrically isolated from each other. Accordingly, a piping defect can be detected, for example, by inspecting whether conduction or non-conduction occurs between the plug PLG1B and the dummy plug DG1. That is, when a piping defect is detected in the TEG formed in a scribe region, there is a high probability that a piping defect has also occurred in the non-volatile memory formed in the chip region. Therefore, a piping defect in the non-volatile memory can be detected by using the TEG in the second related technique. In particular, according to the second related technique, even if the width L1 in the X direction of the insulating region STI1B illustrated in FIG. 4 is reduced, the dummy plug DG1 can still be disposed.

However, the present inventor has newly found that there is room for improvement in the second related technique. The following describes findings newly obtained by the present inventor.

As illustrated in FIG. 4, the TEG in the second related technique includes an insulating region 10A and an insulating region 10B without forming the active region OD2B and the active region OD5B described in the first related technique illustrated in FIG. 3.

As a result, the TEG in the second related technique has a larger area of insulating regions than the non-volatile memory illustrated in FIG. 1.

For example, not only the insulating region STI1B, the insulating region STI2B, the insulating region STI3B, and the insulating region STI4B, but also the insulating region 10A and the insulating region 10B are formed by embedding an insulating film in trenches. When forming the trenches, etching is used. The shape of a trench formed by etching is affected by the area to be etched (first factor).

The insulating region 10A includes portions that overlap with the control gate electrode CG1 and the memory gate electrode MG1 in plan view. The insulating region 10A includes portions that overlap with the control gate electrode CG2 and the memory gate electrode MG2 in plan view. The insulating region 10B includes portions that overlap with the control gate electrode CG3 and the memory gate electrode MG3 in plan view. The insulating region 10B includes portions that overlap with the control gate electrode CG4 and the memory gate electrode MG4 in plan view. As a result, a level difference is generated between an upper surface of the insulating region 10A and an upper surface of the semiconductor substrate, and between an upper surface of the insulating region 10B and the upper surface of the semiconductor substrate. Due to the influence of the level difference, the processed shapes of the control gate electrode CG1, the control gate electrode CG2, the control gate electrode CG3, and the control gate electrode CG4, as well as the heights of the insulating region 10A and the insulating region 10B, are affected (second factor).

For example, in FIG. 1, the active region OD2A is formed between the insulating region STI1A and the insulating region STI2A, whereas in FIG. 4, the insulating region 10A is formed between the insulating region STI1B and the insulating region STI2B. Accordingly, the processed shape of the portion of the control gate electrode CG1A that is located on the active region OD2A in FIG. 1 differs from the processed shape of the portion of the control gate electrode CG1B that is located on the insulating region 10A in FIG. 4. Accordingly, the shape of the interlayer insulating film formed adjacent to the control gate electrode CG1A also differs from the shape of the interlayer insulating film formed adjacent to the control gate electrode CG1B. Consequently, the probability of voids being generated in the interlayer insulating film differs between the non-volatile memory illustrated in FIG. 1 and the TEG illustrated in FIG. 4. That is, the probability of a piping defect occurring differs between the non-volatile memory illustrated in FIG. 1 and the TEG illustrated in FIG. 4.

As a result, the first factor and the second factor affect the manner in which a piping defect occurs. That is, the manner in which a piping defect occurs in the TEG in the second related technique may differ from that in the non-volatile memory illustrated in FIG. 1. For example, while a piping defect occurs in the TEG in the second related technique, it is possible that no piping defect occurs in the non-volatile memory illustrated in FIG. 1. Conversely, while no piping defect occurs in the TEG in the second related technique, it is possible that a piping defect occurs in the non-volatile memory illustrated in FIG. 1. Thus, in the second related technique, there is a possibility that a piping defect cannot be detected with high accuracy.

Accordingly, the following describes the technical concept of the present disclosure.

### Basic Concept

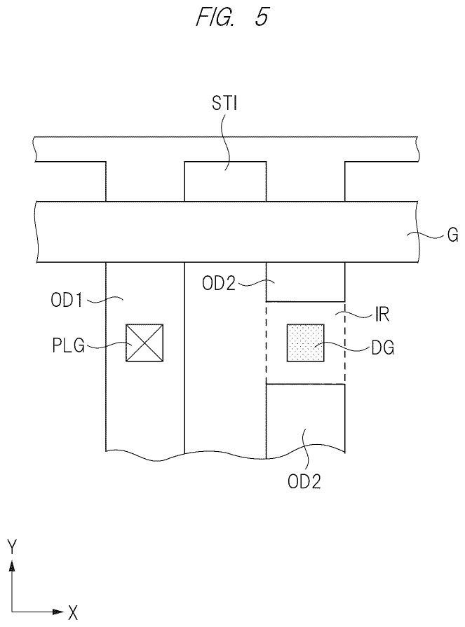

FIG. 5 is a diagram illustrating the basic concept.

In FIG. 5, the TEG includes a gate electrode G, an active region OD1, an active region OD2, an insulating region STI, an insulating region IR, a plug PLG, and a dummy plug DG.

The active region OD1 and the active region OD2 have a portion that is spaced apart from each other in the X direction. The insulating region IR is formed so as to be in contact with the active region OD2. The insulating region IR is spaced from the gate electrode G in plan view. The plug PLG is formed on the active region OD1. The dummy plug DG is formed on the insulating region IR. The dummy plug DG is disposed adjacent to the plug PLG.

In the TEG configured as described above, the plug PLG is electrically connected to the active region OD1. When no piping defect exists between the plug PLG and the dummy plug DG, the dummy plug DG is electrically floating. When a piping defect exists between the plug PLG and the dummy plug DG, the dummy plug DG becomes electrically connected to the plug PLG.

Accordingly, a piping defect can be detected by inspecting whether conduction or non-conduction occurs between the plug PLG and the dummy plug DG. That is, when a piping defect is detected in the TEG formed in a scribe region, there is a high probability that a piping defect has also occurred in a semiconductor device formed in a chip region. Therefore, a piping defect in the semiconductor device can be detected by using the TEG based on the basic concept.

As illustrated in FIG. 5, in the basic concept, the insulating region IR is spaced from the gate electrode G in plan view, unlike the insulating region 10A in the second related technique illustrated in FIG. 4. That is, in the basic concept, the insulating region IR does not have a portion that overlaps with the gate electrode G in plan view.

Accordingly, even when the insulating region IR is formed, the processed shape of the gate electrode G is not affected. In other words, even if the insulating region IR is formed, it does not affect the manner in which a piping defect occurs. That is, it is possible to suppress a difference in the manner in which a piping defect occurs between the TEG based on the basic concept and a semiconductor device formed in a chip region. Therefore, according to the basic concept, a piping defect can be detected with high accuracy.

In the following, a first embodiment implementing the basic idea will be described.

### First Embodiment

A semiconductor wafer in the first embodiment includes a plurality of chip regions and a scribe region that partitions the plurality of chip regions. A non-volatile memory is formed in each of the plurality of chip regions. A TEG formed in the scribe region is a pattern that detects a piping defect in the non-volatile memory.

### <<Configuration of TEG>>

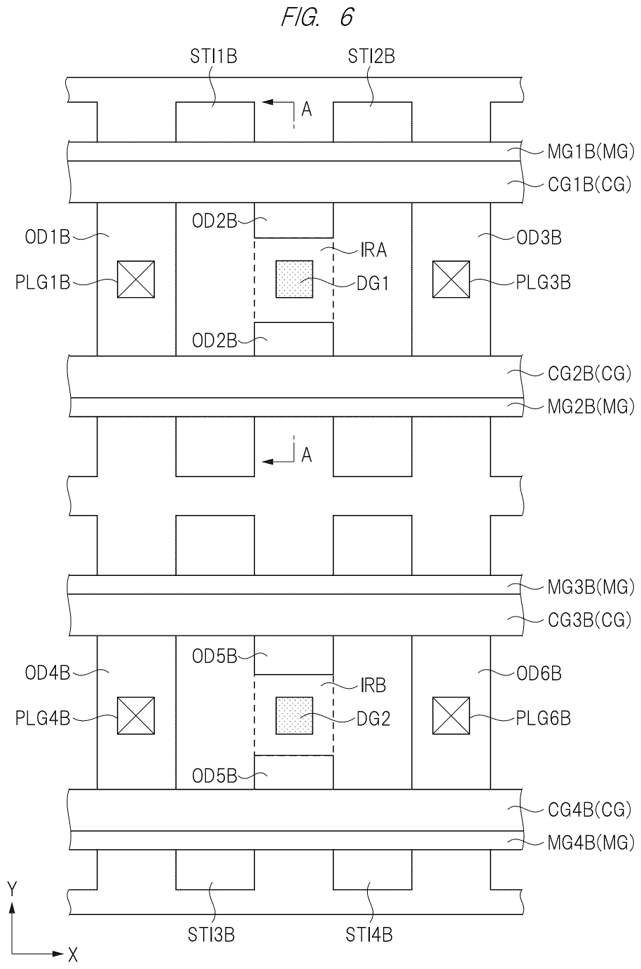

FIG. 6 is a diagram illustrating a layout of the TEG in the first embodiment.

In FIG. 6, the TEG includes a control gate electrode CG1B, a control gate electrode CG2B, a control gate electrode CG3B, a control gate electrode CG4B, a memory gate electrode MG1B, a memory gate electrode MG2B, a memory gate electrode MG3B, a memory gate electrode MG4B, an active region OD1B, an active region OD2B, an active region OD3B, an active region OD4B, an active region OD5B, an active region OD6B, an insulating region STI1B, an insulating region STI2B, an insulating region STI3B, an insulating region STI4B, a plug PLG1B, a plug PLG3B, a plug PLG4B, a plug PLG6B, a dummy plug DG1 and a dummy plug DG2.

The active region OD2B is adjacent to the active region OD1B in the X direction. The insulating region IRA is adjacent to the active region OD2B in the Y direction, which is orthogonal to the X direction. The insulating region IRA is formed so as not to overlap with the control gate electrode CG1B in plan view. The insulating region IRA is formed so as not to overlap with the control gate electrode CG1B in plan view.

The insulating region IRA is spaced from the control gate electrode CG1B in plan view. The insulating region IRA is also spaced from the control gate electrode CG2B in plan view. The insulating region IRA includes a trench and an insulating film embedded in the trench.

The insulating region IRB is spaced from the control gate electrode CG3B in plan view. The insulating region IRB is also spaced from the control gate electrode CG4B in plan view. The insulating region IRB includes a trench and an insulating film embedded in the trench. Each of the insulating region STI1B, the insulating region STI2B, the insulating region STI3B, and the insulating region STI4B is composed of a trench and an insulating film embedded in the trench.

The plug PLG1B is connected to the active region OD1B. The dummy plug DG1 is connected to the insulating region IRA.

The dummy plug DG1 is located, in plan view, between the control gate electrode CG1B and the control gate electrode CG2B. The dummy plug DG1 is located, in plan view, between the insulating region STI1B and the insulating region STI2B. The dummy plug DG1 is located, in plan view, between the plug PLG1B and the plug PLG3B. The dummy plug DG1 is formed on the insulating region IRA.

The dummy plug DG2 is located, in plan view, between the control gate electrode CG3B and the control gate electrode CG4B. The dummy plug DG2 is located, in plan view, between the insulating region STI3B and the insulating region STI4B. The dummy plug DG2 is located, in plan view, between the plug PLG4B and the plug PLG6B. The dummy plug DG2 is formed on the insulating region IRB.

As illustrated in FIG. 6, in the first embodiment, the insulating region IRA is spaced from the control gate electrode CG1B and the control gate electrode CG2B in plan view. The insulating region IRA does not have any portion overlapping, in plan view, with the control gate electrode CG1B and the control gate electrode CG2B.

The insulating region IRB is spaced from the control gate electrode CG3B and the control gate electrode CG4B in plan view. The insulating region IRB does not have any portion overlapping, in plan view, with the control gate electrode CG3B and the control gate electrode CG4B.

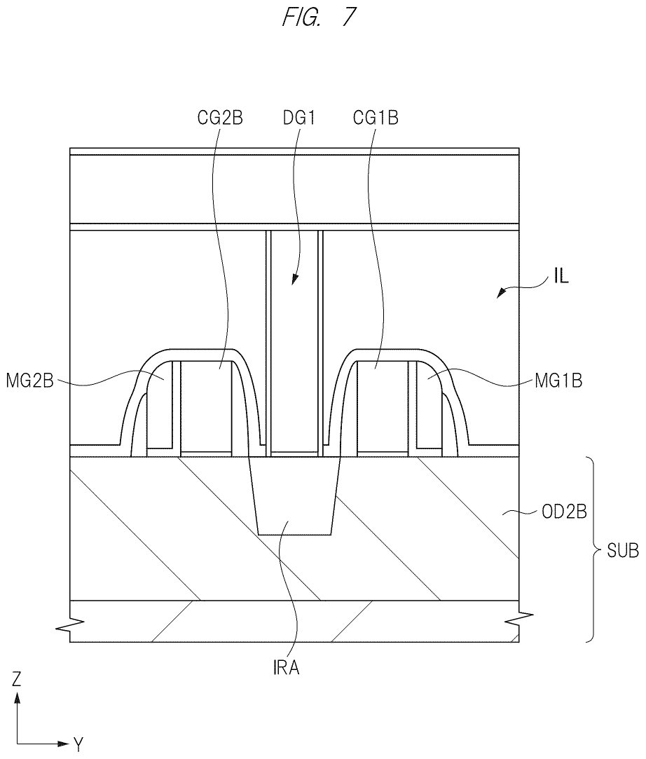

FIG. 7 is a cross-sectional view of the TEG taken along line A-A in FIG. 6.

In FIG. 7, the active region OD2B is formed in a semiconductor substrate SUB. On the active region OD2B, the control gate electrode CG1B is formed via a gate insulating film. On the active region OD2B, the control gate electrode CG2B is formed via the gate insulating film. In the Y direction, the control gate electrode CG1B and the control gate electrode CG2B are spaced apart from each other. On one sidewall of the control gate electrode CG1B, the memory gate electrode MG1B is formed via a stacked insulating film (ONO film). On one sidewall of the control gate electrode CG2B, the memory gate electrode MG2B is formed via the stacked insulating film (ONO film).

An interlayer insulating film IL is formed on the active region OD2B so as to cover the control gate electrode CG1B, the memory gate electrode MG1B, the control gate electrode CG2B, and the memory gate electrode MG2B. The dummy plug DG1 is formed in the interlayer insulating film IL. The insulating region IRA is formed in the active region OD2B. The dummy plug DG1 is connected to the insulating region IRA. The dummy plug DG1 is located between the control gate electrode CG1B and the control gate electrode CG2B in the Y direction. In FIG. 7, the control gate electrode CG1B and the control gate electrode CG2B are not formed on the insulating region IRA.

Therefore, as can be seen with reference to FIGS. 2 and 7, the cross-sectional shape of the portion of the control gate electrode CG1B located on the active region OD2B is the same as the cross-sectional shape of the portion of the control gate electrode CG1A located on the active region OD2A. The cross-sectional shape of the portion of the control gate electrode CG2B located on the active region OD2B is the same as the cross-sectional shape of the portion of the control gate electrode CG2A located on the active region OD2A.

That is, even if the insulating region IRA is formed, the processed shapes of the control gate electrode CG and the memory gate electrode MG are not affected. Also, even if the insulating region IRB is formed, the processed shapes of the control gate electrode CG and the memory gate electrode MG are not affected.

According to the first embodiment, even if the insulating region IRA is formed, it does not affect the manner in which a piping defect occurs. Similarly, even if the insulating region IRB is formed, it does not affect the manner in which a piping defect occurs. That is, the first embodiment can suppress a difference between the manner in which a piping defect occurs in the TEG and the manner in which a piping defect occurs in the semiconductor device formed in the chip region. Therefore, according to the first embodiment, a piping defect can be accurately detected.

In the TEG of the first embodiment, for example, as illustrated in FIG. 6, when a piping defect occurs between the plug PLG1B and the dummy plug DG1, which are adjacent to each other, the plug PLG1B and the dummy plug DG1 become electrically connected. Whereas, when no piping defect occurs between the plug PLG1B and the dummy plug DG1, the dummy plug DG1 is electrically insulated from the plug PLG1B.

Therefore, the presence or absence of a piping defect can be detected by inspecting whether conduction or non-conduction occurs between the plug PLG1B and the dummy plug DG1. That is, when a piping defect is detected in the TEG formed in a scribe region, there is a high probability that a piping defect has also occurred in the non-volatile memory formed in a chip region. Accordingly, by using the TEG, it is possible to detect a piping defect in the non-volatile memory.

In this regard, in the first embodiment, a potential contrast method is used to detect a piping defect. A method of detecting a piping defect in the first embodiment will be described below.

### <<Method of Detecting Piping Defect>>

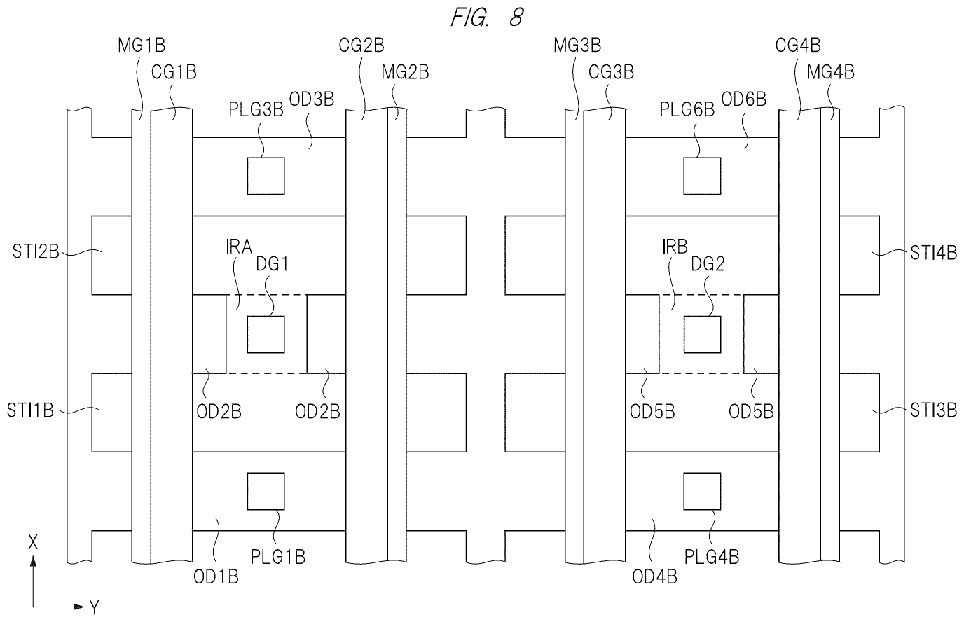

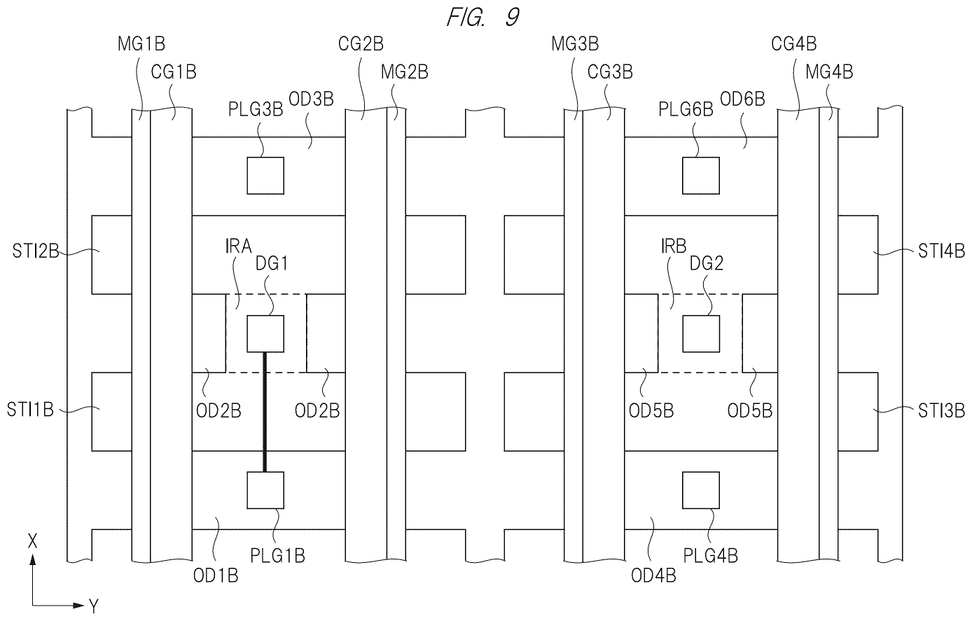

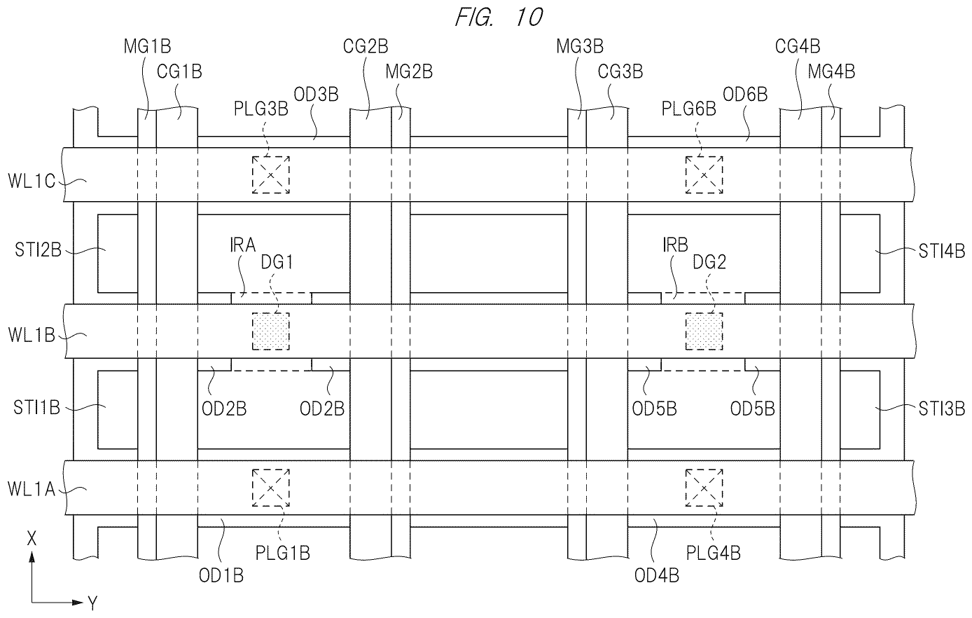

FIG. 8 is a diagram illustrating a layout of the TEG in the first embodiment in a state where no piping defect is present. The observation results obtained when the TEG with no piping defect is inspected using the potential contrast method will be described. In FIG. 8, bright and dark contrasts are observed in the plugs by the potential contrast method. For example, the plug PLG1B electrically connected to the active region OD1B is observed as bright. The plug PLG3B electrically connected to the active region OD3B is observed as bright. The plug PLG4B electrically connected to the active region OD4B is observed as bright. The plug PLG6B electrically connected to the active region OD6B is observed as bright.

Whereas, for example, the dummy plug DG1 formed on the insulating region IRA is not electrically connected to the active region OD2B. In other words, the potential of the dummy plug DG1 is in a floating state. As a result, the dummy plug DG1 is observed as dark. The dummy plug DG2 formed on the insulating region IRB is not electrically connected to the active region OD5B. In other words, the potential of the dummy plug DG2 is in a floating state. As a result, the dummy plug DG2 is observed as dark.

FIG. 9 is a diagram illustrating a layout of the TEG in a state where a piping defect is present in the first embodiment. The observation results obtained when the TEG with a piping defect is inspected using the potential contrast method will be described.

As illustrated in FIG. 9, a piping defect is present between the plug PLG1B and the dummy plug DG1. In FIG. 9, for example, the plug PLG1B electrically connected to the active region OD1B is observed as bright. The plug PLG3B electrically connected to the active region OD3B is observed as bright. The plug PLG4B electrically connected to the active region OD4B is observed as bright. The plug PLG6B electrically connected to the active region OD6B is observed as bright.

Whereas, for example, the dummy plug DG2 formed on the insulating region IRB is not electrically connected to the active region OD5B. In other words, the potential of the dummy plug DG2 is in a floating state. As a result, the dummy plug DG2 is observed as dark. On the other hand, the dummy plug DG1 formed on the insulating region IRA is electrically connected to the plug PLG1B formed on the active region OD1B. As a result, the dummy plug DG1 is observed as bright.

Accordingly, when comparing FIG. 8 and FIG. 9, it can be seen that, the dummy plug DG1 is observed as bright instead of dark, due to the piping defect. As a result, according to the first embodiment, a piping defect can be detected.

Next, a method of manufacturing a semiconductor device including the above-described method of detecting a piping defect will be described.

### <<Method of Manufacturing Semiconductor Device>>

The manufacturing process of the semiconductor device includes a step of wafer. The step of wafer includes a step of substrate and a step of wiring. First, a semiconductor wafer having a plurality of chip regions and a scribe region that partitions the plurality of chip regions is prepared. After performing the step of substrate on the semiconductor wafer, an interlayer insulating film formation step and a contact plug formation step, which are part of the step of wiring, are performed. The semiconductor wafer after the contact plug formation step has the following structure.

A TEG is formed in the scribe region. The TEG includes a first active region, a second active region, a first gate electrode, an insulating region, a first plug, and a second plug. The first active region is formed in the semiconductor substrate. The second active region is formed in the semiconductor substrate. The second active region is adjacent to the first active region in a first direction. The first gate electrode is formed over the first active region and the second active region. The first gate electrode extends in the first direction. The insulating region is adjacent to the second active region in a second direction orthogonal to the first direction. The insulating region is formed in the semiconductor substrate so as not to overlap with the first gate electrode in plan view. The first plug is formed in the interlayer insulating film. The first plug is connected to the first active region. The second plug is formed in the interlayer insulating film. The second plug is connected to the insulating region.

Thereafter, the method of manufacturing the semiconductor device according to the first embodiment includes a step of detecting a piping defect between the first plug and the second plug. Here, the step of detecting a piping defect between the first plug and the second plug uses a potential contrast method.

Subsequently, a step of forming a first wire and a second wire is performed. The step of forming the first wire and the second wire is included in the step of wiring. The first wire and the second wire are formed on the interlayer insulating film. The first wire is in contact with the first plug. The second wire is in contact with the second plug.

In the first embodiment, as described above, after performing the step of substrate and part of the step of wiring (up to the contact plug formation step), a step of detecting a piping defect is performed. Therefore, according to the first embodiment, a piping defect can be accurately detected at an early stage before completion of the step of wafer. That is, according to the first embodiment, it is possible to suppress the fabrication of defective products having a piping defect. Specifically, a piping defect can be detected at an early stage before performing the step of forming a first wiring and a second wiring after the contact plug formation step.

### Second Embodiment

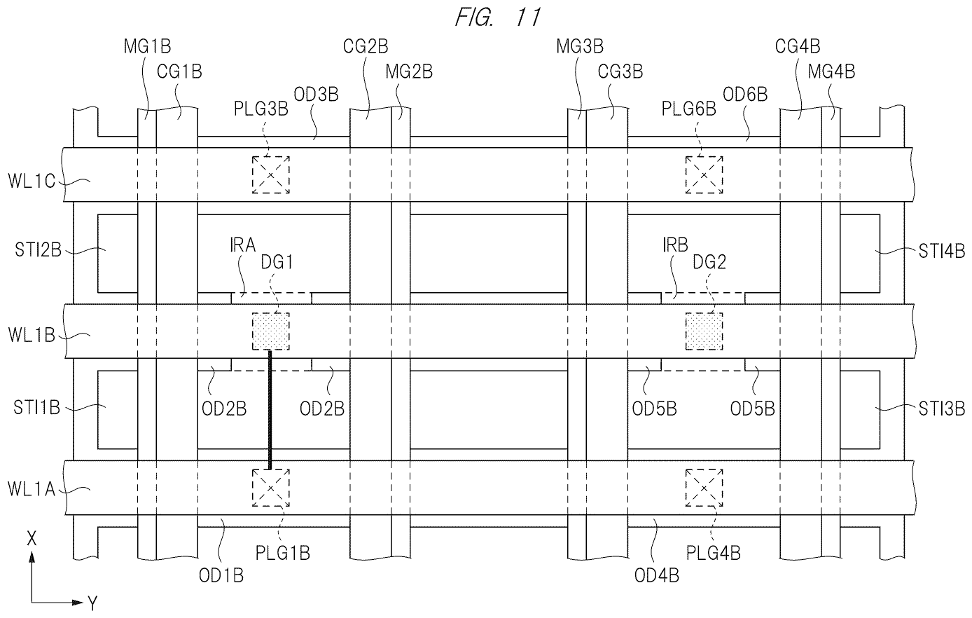

In the second embodiment, an example is described in which a conduction check using wirings is employed as a method of detecting a piping defect. In the second embodiment, a wiring is used. Therefore, the TEG includes, in addition to the configuration of the TEG illustrated in FIG. 6, a wiring WL1A, a wiring WL1B, and a wiring WL1C. The wiring WL1A is in contact with the plug PLG1B and the plug PLG4B. The wiring WL1B is in contact with the dummy plug DG1 and the dummy plug DG2. The wiring WL1C is in contact with the plug PLG3B and the plug PLG6B (see FIG. 10).

FIG. 10 is a diagram illustrating a layout of the TEG in the second embodiment in a state where no piping defect is present.

When a conduction check is performed between the wiring WL1A and the wiring WL1B, it is determined that the wiring WL1A and the wiring WL1B are not electrically connected, because there are no piping defect between the plug PLG1B and the dummy plug DG1, and no piping defect between the plug PLG4B and the dummy plug DG2.

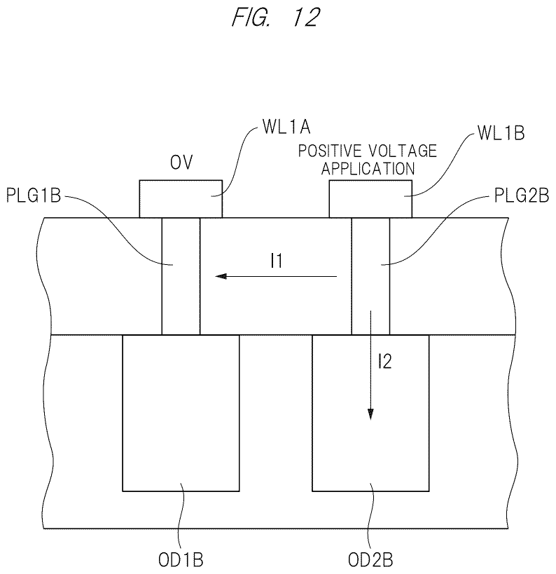

FIG. 11 is a diagram illustrating a layout of the TEG in the second embodiment in a state where a piping defect is present. Specifically, as illustrated in FIG. 11, a piping defect occurs between the plug PLG1B and the dummy plug DG1.

When a conduction check is performed between the wiring WL1A and the wiring WL1B, it is determined that the wiring WL1A is electrically connected to the wiring WL1B because a piping defect is present between the plug PLG1B and the dummy plug DG1.

Accordingly, when comparing FIG. 10 and FIG. 11, the result of the conduction check between the wiring WL1A and the wiring WL1B is “electrically connected” instead of “electrically disconnected”, due to the piping defect. From this, a piping defect can be detected by detecting a state in which the wiring WL1A and the wiring WL1B are electrically connected to each other.

Next, a method of manufacturing a semiconductor device including the above-described method of detecting a piping defect will be described.

Similarly to the first embodiment, after performing the step of substrate on the semiconductor wafer, an interlayer insulating film formation step and the contact plug formation step, which are part of the step of wiring, are performed. Furthermore, in the second embodiment, the wiring WL1A in contact with the plug PLG1B and the wiring WL1B in contact with the dummy plug DG1 are formed.

Thereafter, in the second embodiment, a piping defect is detected by detecting an electrical connection between the wiring WL1A and the wiring WL1B by a conduction check.

In the second embodiment, as described above, after performing the step of substrate and part of the step of wiring, a step of detecting a piping defect is performed. Specifically, after performing a step of forming the wiring WL1A, the wiring WL1B, and the wiring WL1C, the step of detecting a piping defect is performed. Therefore, according to the second embodiment, a piping defect can be accurately detected at an early stage before completion of the step of wafer. A piping defect can be detected before performing a step of forming wirings that are located above the wiring WL1A, the wiring WL1B, and the wiring WL1C.

In the second embodiment, the conduction check using wirings is employed as a method of detecting a piping defect, instead of the potential contrast method. In this regard, the conduction check using wirings has a shorter measurement time compared to the potential contrast method. Therefore, according to the second embodiment, the step of detecting a piping defect can be performed without significantly affecting the throughput in the manufacturing process of the semiconductor device.

The advantages of the second embodiment will be described below.

FIG. 12 is a diagram illustrating a conduction check in an examination example.

In FIG. 12, the plug PLG1B is formed on the active region OD1B. The wiring WL1A is formed on the plug PLG1B. The wiring WL1A is electrically connected to the active region OD1B via the plug PLG1B.

The plug PLG2B is formed on the active region OD2B. The wiring WL1B is formed on the plug PLG2B. The wiring WL1B is electrically connected to the active region OD2B via the plug PLG2B.

A conduction check is performed between the wiring WL1A and the wiring WL1B. Specifically, by applying 0 V to the wiring WL1A and applying a positive voltage to the wiring WL1B, the conduction check is performed between the wiring WL1A and the wiring WL1B.

For example, when a piping defect occurs between the plug PLG1B and the plug PLG2B, a leakage current I1 flows between the plug PLG1B and the plug PLG2B. Therefore, when a piping defect occurs between the plug PLG1B and the plug PLG2B, the conduction check detects that the wiring WL1A and the wiring WL1B are electrically connected to each other.

However, in the examination example, even when no piping defect occurs between the plug PLG1B and the plug PLG2B, a leakage current I2 flows due to a pn junction included in the active region OD2B. Therefore, even when no piping defect occurs between the plug PLG1B and the plug PLG2B, the leakage current I2 is detected in the conduction check between the wiring WL1A and the wiring WL1B.

In the examination example, when the short circuit caused by the piping defect is small, that is, when the leakage current I1 caused by the piping defect is small, there is a possibility that the difference between the leakage current I2 and the leakage current I1 is too small to identify the presence of a piping defect, even if the conduction check detects that the wiring WL1A and the wiring WL1B are electrically connected. In other words, in the examination example, it is difficult to detect a piping defect with high accuracy.

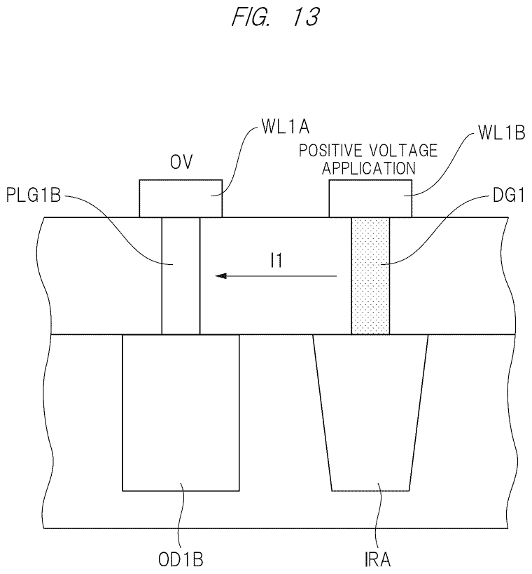

FIG. 13 is a diagram illustrating the conduction check in the second embodiment.

In FIG. 13, the plug PLG1B is formed on the active region OD1B. The wiring WL1A is formed on the plug PLG1B. The wiring WL1A is electrically connected to the active region OD1B via the plug PLG1B. Meanwhile, the dummy plug DG1 is formed on the insulating region IRA. The wiring WL1B is formed on the dummy plug DG1.

A conduction check is performed between the wiring WL1A and the wiring WL1B. Specifically, by applying 0 V to the wiring WL1A and applying a positive voltage to the wiring WL1B, the conduction check is performed between the wiring WL1A and the wiring WL1B.

For example, when a piping defect occurs between the plug PLG1B and the dummy plug DG1, a leakage current I1 flows between the plug PLG1B and the dummy plug DG1. Therefore, when a piping defect occurs between the plug PLG1B and the dummy plug DG1, the conduction check detects that the wiring WL1A and the wiring WL1B are electrically connected to each other.

In the second embodiment, as illustrated in FIG. 13, the insulating region IRA is formed. Therefore, the leakage current I2 illustrated in FIG. 12 does not flow. Therefore, when no piping defect occurs between the plug PLG1B and the dummy plug DG1, the conduction check detects that the wiring WL1A and the wiring WL1B are not electrically connected to each other.

Therefore, in the second embodiment, when the conduction check detects that the wiring WL1A and the wiring WL1B are electrically connected to each other, it is understood that a piping defect has occurred. In other words, in the second embodiment, a piping defect can be detected with high accuracy.

### Third Embodiment

A semiconductor wafer in a third embodiment includes a plurality of chip regions and a scribe region that partitions the plurality of chip regions. A DRAM is formed in each of the plurality of chip regions. A TEG formed in the scribe region is a pattern for detecting a piping defect in the DRAM.

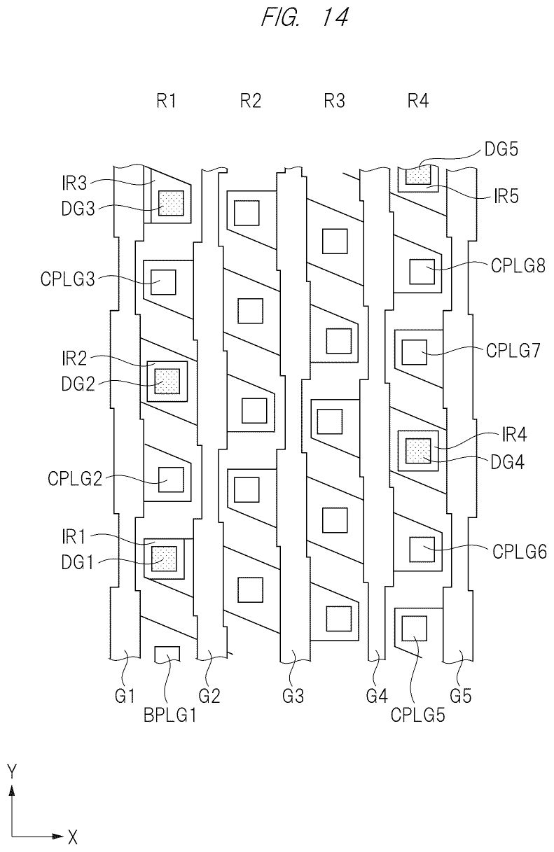

FIG. 14 is a diagram illustrating a layout of the TEG in the third embodiment in a state where no piping defect is present. In FIG. 14, the TEG includes a gate electrode G1, a gate electrode G2, a gate electrode G3, a gate electrode G4, and a gate electrode G5. The gate electrode G1, the gate electrode G2, the gate electrode G3, the gate electrode G4, and the gate electrode G5 are disposed at predetermined intervals in the X direction. Each of the gate electrode G1, the gate electrode G2, the gate electrode G3, the gate electrode G4, and the gate electrode G5 extends in the Y direction.

A plurality of plugs is disposed between the gate electrode G1 and the gate electrode G2. The row of plugs between the gate electrode G1 and the gate electrode G2 is referred to as row R1. A plurality of plugs is disposed between the gate electrode G2 and the gate electrode G3. The row of plugs between the gate electrode G2 and the gate electrode G3 is referred to as row R2. A plurality of plugs is disposed between the gate electrode G3 and the gate electrode G4. The row of plugs between the gate electrode G3 and the gate electrode G4 is referred to as row R3. A plurality of plugs is disposed between the gate electrode G4 and the gate electrode G5. The row of plugs between the gate electrode G4 and the gate electrode G5 is referred to as row R4. In the third embodiment, an example of the TEG is illustrated in row R1, and another example of the TEG is illustrated in row R4. It should be noted that the illustrations of the TEG in rows R2 and R3 are omitted.

Focus is placed on row R1. In row R1, from the bottom upward, a bit plug BPLG1, a dummy plug DG1, a capacitor plug CPLG2, a dummy plug DG2, a capacitor plug CPLG3, and a dummy plug DG3 are disposed. The bit plug BPLG1, the capacitor plug CPLG2, and the capacitor plug CPLG3 are formed on active regions. The dummy plug DG1 is formed on an insulating region IR1. The dummy plug DG2 is formed on an insulating region IR2. The dummy plug DG3 is formed on an insulating region IR3.

In FIG. 14, bright and dark contrasts are observed in the plugs by the potential contrast method.

For example, the bit plug BPLG1 is observed as bright. The dummy plug DG1 is observed as dark. The capacitor plug CPLG2 is observed as bright. The dummy plug DG2 is observed as dark. The capacitor plug CPLG3 is observed as bright. The dummy plug DG3 is observed as dark.

Focus is placed on row R4. In row R4, from the bottom upward, a capacitor plug CPLG5, a capacitor plug CPLG6, a dummy plug DG4, a capacitor plug CPLG7, a capacitor plug CPLG8, and a dummy plug DG5 are disposed. The capacitor plug CPLG5, the capacitor plug CPLG6, the capacitor plug CPLG7, and the capacitor plug CPLG8 are formed on active regions. The dummy plug DG4 is formed on an insulating region IR4. The dummy plug DG5 is formed on an insulating region IR5.

In FIG. 14, bright and dark contrasts are observed in the plugs by the potential contrast method.

For example, the capacitor plug CPLG5 is observed as bright. The capacitor plug CPLG6 is observed as bright. The dummy plug DG4 is observed as dark. The capacitor plug CPLG7 is observed as bright. The capacitor plug CPLG8 is observed as bright. The dummy plug DG5 is observed as dark.

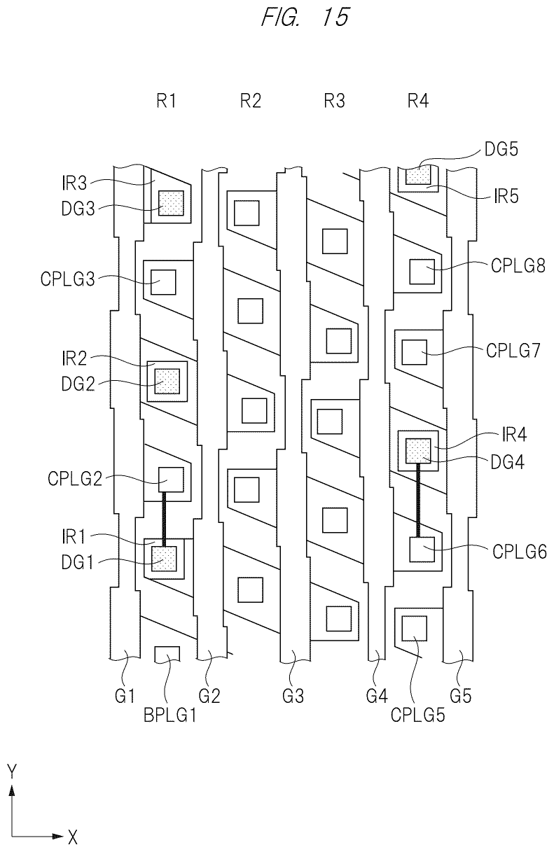

FIG. 15 is a diagram illustrating a layout of the TEG in the third embodiment in a state where a piping defect is present. Specifically, as illustrated in FIG. 15, a piping defect has occurred between the dummy plug DG1 and the capacitor plug CPLG2. In addition, a piping defect has occurred between the capacitor plug CPLG6 and the dummy plug DG4.

In FIG. 15, bright and dark contrasts are observed in the plugs by the potential contrast method.

When focus is placed on row R1, the bit plug BPLG1 is observed as bright. The dummy plug DG1 is observed as bright. The capacitor plug CPLG2 is observed as bright. The dummy plug DG2 is observed as dark. The capacitor plug CPLG3 is observed as bright. The dummy plug DG3 is observed as dark.

When focus is placed on row R4, the capacitor plug CPLG5 is observed as bright. The capacitor plug CPLG6 is observed as bright. The dummy plug DG4 is observed as bright. The capacitor plug CPLG7 is observed as bright. The capacitor plug CPLG8 is observed as bright. The dummy plug DG5 is observed as dark.

Therefore, focusing on row R1 and comparing FIG. 14 and FIG. 15, the dummy plug DG1 is observed as bright, rather than dark, due to the piping defect. As a result, as illustrated in FIG. 15, each of the bit plug BPLG1, the dummy plug DG1, and the capacitor plug CPLG2 is observed as bright. By detecting this state, according to the third embodiment, it is possible to detect a piping defect that has occurred between the dummy plug DG1 and the capacitor plug CPLG2.

By focusing on row R4 and comparing FIG. 14 and FIG. 15, the dummy plug DG4 is observed as bright, rather than dark, due to the piping defect. As a result, as illustrated in FIG. 15, each of the capacitor plug CPLG5, the capacitor plug CPLG6, and the dummy plug DG4 is observed to be bright. By detecting this state, it is possible to detect the piping defect that has occurred between the capacitor plug CPLG6 and the dummy plug DG4.

The TEG described in row R1 is configured such that the dummy plugs are formed alternately regardless of whether the adjacent plug is a bit plug or a capacitor plug, and an insulating region is formed under each dummy plug. In this case, it is possible to detect a piping defect between adjacent plugs, regardless of whether the plugs are bit plugs or capacitor plugs.

On the other hand, in the TEG described in row R4, for example, only the bit plugs (or only the capacitor plugs) are configured as dummy plugs, and the insulating regions are formed under the dummy plugs. In this case, the layout of the insulating regions and the dummy plugs becomes easier. That is, the TEG can be easily formed.

### Fourth Embodiment

A semiconductor wafer in a fourth embodiment includes a plurality of chip regions and a scribe region that partitions the plurality of chip regions. An SRAM is formed in each of the plurality of chip regions. A TEG formed in the scribe region is a pattern for detecting a piping defect in the SRAM.

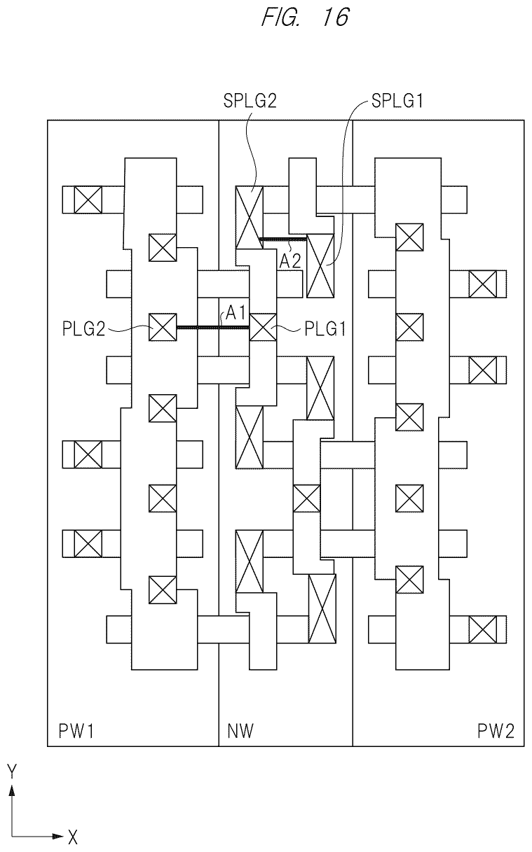

FIG. 16 is a diagram illustrating a layout of the TEG in an examination example.

The TEG illustrated in FIG. 16 has, for example, a pattern similar to a layout of an SRAM formed in the chip region. In FIG. 16, the TEG includes an n-type well NW, a p-type well PW1, and a p-type well PW2.

A plurality of load transistors constituting the SRAM is formed in the n-type well NW. Each load transistor is composed of a p-type MOSFET. A plurality of drive transistors constituting the SRAM is formed in the p-type well PW1. Each drive transistor is composed of an n-type MOSFET. A plurality of drive transistors constituting the SRAM is formed in the p-type well PW2. Each drive transistor is composed of an n-type MOSFET.

In FIG. 16, focus is placed on the plug PLG1 and the plug PLG2.

Bright and dark contrasts of the plug PLG1 and the plug PLG2 are observed using the potential contrast method. When a potential condition is used in which the plug PLG1 is observed as bright in the region of the n-type well NW, the plug PLG2 is observed as dark in the region of the p-type well PW1.

Accordingly, if no piping defect is present between the plug PLG1 and the plug PLG2, the plug PLG1 is observed as bright, whereas the plug PLG2 is observed as dark.

In contrast, if a piping defect A1 has occurred between the plug PLG1 and the plug PLG2, the plug PLG1 and the plug PLG2 are electrically connected via the piping defect A1. As a result, the plug PLG2 is observed as bright.

From the above, the plug PLG2 is observed as bright, rather than dark, due to the piping defect A1. By detecting this state, when using the TEG illustrated in FIG. 16, it is possible to detect the piping defect A1 that has occurred between the plug PLG1 and the plug PLG2.

In FIG. 16, focus is placed on a shared plug SPLG1 and a shared plug SPLG2. The shared plug SPLG1 and the shared plug SPLG2 are both located within the n-type well NW in plan view. Therefore, when no piping defect has occurred between the shared plug SPLG1 and the shared plug SPLG2, the shared plug SPLG1 is observed as bright, and the shared plug SPLG2 is also observed as bright.

When a piping defect A2 has occurred between the shared plug SPLG1 and the shared plug SPLG2, the shared plug SPLG1 and the shared plug SPLG2 are electrically connected to each other via the piping defect A2. As a result, the shared plug SPLG2 is observed as bright. That is, when using the TEG illustrated in FIG. 16, regardless of whether the piping defect A2 has occurred between the shared plug SPLG1 and the shared plug SPLG2, both the shared plug SPLG1 and the shared plug SPLG2 are observed as bright in either case.

Here, in an SRAM cell, the distance between the shared plug SPLG1 and the shared plug SPLG2 is smaller than the distance between the plug PLG1 and the plug PLG2, and thus a short circuit due to a piping defect is more likely to occur.

However, in the TEG illustrated in FIG. 16, it is not possible to detect the piping defect A2 that occurs between the shared plug SPLG1 and the shared plug SPLG2.

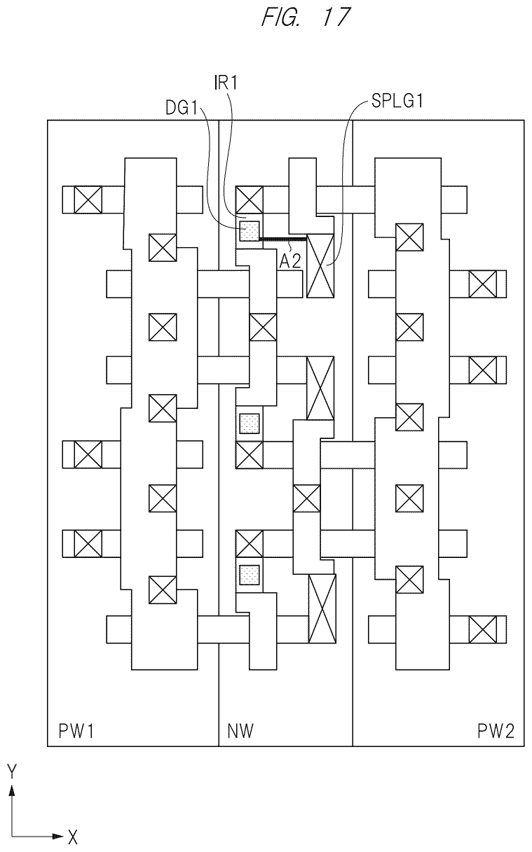

Therefore, the TEG illustrated in FIG. 17 is used.

FIG. 17 illustrates a layout of the TEG in the fourth embodiment.

The TEG illustrated in FIG. 17 includes a dummy plug DG1 formed on an insulating region IR1. In FIG. 17, when no piping defect A2 has occurred between the shared plug SPLG1 and the dummy plug DG1, the shared plug SPLG1 is observed as bright. On the other hand, although the dummy plug DG1 is formed in the n-type well NW, since the dummy plug DG1 is formed on the insulating region IR1, the dummy plug DG1 is observed as dark.

In contrast, when the piping defect A2 has occurred between the shared plug SPLG1 and the dummy plug DG1, the shared plug SPLG1 and the dummy plug DG1 are electrically connected to each other via the piping defect A2. As a result, the dummy plug DG1 is observed as bright. From the above, the dummy plug DG1 is observed as bright, rather than dark, due to the piping defect A2. By detecting this state, when using the TEG illustrated in FIG. 17, it is possible to detect the piping defect A2 that has occurred between the shared plug SPLG2 and the dummy plug DG1.

Accordingly, by using the TEG illustrated in FIG. 17 of the fourth embodiment, it is possible to detect the piping defect A2 between the shared plug SPLG1 and the dummy plug DG1.

That is, when the piping defect A2 is detected in the TEG formed in the scribe region, there is a high probability that a piping defect has also occurred between the shared plug SPLG1 and the shared plug SPLG2 in the SRAM formed in the chip region.

Therefore, by using the TEG illustrated in FIG. 17 of the fourth embodiment, it is possible to detect a piping defect in the SRAM. In particular, since the distance between the shared plug SPLG1 and the shared plug SPLG2 is shorter than the distance between the plug PLG1 and the plug PLG2, a piping defect is more likely to occur. In this regard, by adopting a method of detecting a piping defect using the TEG of the fourth embodiment, it is possible to accurately detect the piping defect occurring between the shared plug SPLG1 and the shared plug SPLG2.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

What is claimed is:

1. A semiconductor wafer comprising:
a semiconductor substrate;
a plurality of chip regions;
a scribe region that partitions the plurality of chip regions; and
an interlayer insulating film formed on the semiconductor substrate,
wherein a TEG is formed in the scribe region, and
wherein the TEG includes:
a first active region formed in the semiconductor substrate;
a second active region formed in the semiconductor substrate, and adjacent to the first active region in a first direction;
a first gate electrode formed on the first active region and the second active region, and extending in the first direction;
an insulating region adjacent to the second active region in a second direction orthogonal to the first direction, and formed in the semiconductor substrate so as not to overlap with the first gate electrode in plan view;
a first plug formed in the interlayer insulating film, and connected to the first active region; and
a second plug formed in the interlayer insulating film, and connected to the insulating region.

2. The semiconductor wafer according to claim 1,
wherein when no piping defect exists between the first plug and the second plug, the second plug is electrically floating, and
wherein when a piping defect exists between the first plug and the second plug, the second plug is electrically connected to the first plug.

3. The semiconductor wafer according to claim 1, further comprising:
a first wiring electrically connected to the first plug; and
a second wiring electrically connected to the second plug.

4. The semiconductor wafer according to claim 3,
wherein the first wiring is formed on the interlayer insulating film and connected to the first plug, and
wherein the second wiring is formed on the interlayer insulating film and connected to the second plug.

5. The semiconductor wafer according to claim 1,
wherein the insulating region includes
a trench formed in the semiconductor substrate, and
an insulating film embedded in the trench.

6. The semiconductor wafer according to claim 1,
wherein a non-volatile memory is formed in each of the plurality of chip regions, and
wherein the TEG is configured to detect presence or absence of a piping defect of the non-volatile memory.

7. The semiconductor wafer according to claim 6,
wherein the TEG includes a second gate electrode extending in the first direction spaced apart from the first gate electrode,
wherein the first active region includes portions that overlap with the first gate electrode and the second gate electrode in plan view,
wherein the second active region includes portions that overlap with the first gate electrode and the second gate electrode in plan view, and
wherein the insulating region is formed so as not to overlap with the first gate electrode and the second gate electrode in plan view.

8. The semiconductor wafer according to claim 1,
wherein a DRAM is formed in each of the plurality of chip regions, and
wherein the TEG is configured to detect presence or absence of a piping defect of the DRAM.

9. The semiconductor wafer according to claim 1,
wherein a SRAM is formed in each of the plurality of chip regions, and
wherein the TEG is configured to detect presence or absence of a piping defect of the SRAM.

10. The semiconductor wafer according to claim 6,
wherein the non-volatile memory includes
a third active region formed in the semiconductor substrate, and
a third gate electrode formed on the third active region, and extending in the first direction.

11. The semiconductor wafer according to claim 10,
wherein a cross-sectional shape of a portion of the first gate electrode located on the second active region is the same as a cross-sectional shape of a portion of the third gate electrode located on the third active region.

12. A method of manufacturing a semiconductor device, comprising the steps of:
(a) preparing a semiconductor wafer having a semiconductor substrate, a plurality of chip regions, a scribe region that partitions the plurality of chip regions, an interlayer insulating film formed on the semiconductor substrate, and a TEG formed in the scribe region; and
(b) detecting a piping defect between a first plug and a second plug,
wherein the TEG includes;
a first active region formed in the semiconductor substrate;
a second active region formed in the semiconductor substrate, and adjacent to the first active region in a first direction;
a first gate electrode formed on the first active region and the second active region, and extending in the first direction;
an insulating region adjacent to the second active region in a second direction orthogonal to the first direction, and formed in the semiconductor substrate so as not to overlap with the first gate electrode in plan view;
the first plug formed in the interlayer insulating film and connected to the first active region; and
the second plug formed in the interlayer insulating film and connected to the insulating region.

13. The method of manufacturing the semiconductor device according to claim 12,
wherein, in the step (b), the piping defect is detected by a potential contrast method.

14. The method of manufacturing the semiconductor device according to claim 13, further comprising,
after the step of (b), a step of forming a wiring.

15. The method of manufacturing the semiconductor device according to claim 12, further comprising:
after the step of (a) and before the step of (b),
a step of forming a first wiring on the interlayer insulating film in contact with the first plug; and
a step of forming a second wiring on the interlayer insulating film in contact with the second plug,
wherein, in the step of (b), the piping defect is detected by detecting an electrical connection between the fist wiring and the second wiring by a conduction check.

16. The method of manufacturing the semiconductor device according to claim 12,
wherein the insulating region includes
a trench formed in the semiconductor substrate, and
an insulating film embedded in the trench.

17. The method of manufacturing the semiconductor device according to claim 12,
wherein a non-volatile memory is formed in each of the plurality of chip regions of the semiconductor wafer prepared in the step of (a), and
wherein the TEG is configured to detect presence or absence of a piping defect of the non-volatile memory.

18. The method of manufacturing the semiconductor device according to claim 17,
wherein the TEG includes a second gate electrode extending in the first direction spaced apart from the first gate electrode,
wherein the first active region includes portions that overlap with the first gate electrode and the second gate electrode in plan view,
wherein the second active region includes portions that overlap with the first gate electrode and the second gate electrode in plan view, and
wherein the insulating region is formed so as not to overlap with the first gate electrode and the second gate electrode in plan view.

19. The method of manufacturing the semiconductor device according to claim 17,
wherein the non-volatile memory includes
a third active region formed in the semiconductor substrate, and
a third gate electrode formed on the third active region, and extending in the first direction.

20. The method of manufacturing the semiconductor device according to claim 19,
wherein a cross-sectional shape of a portion of the first gate electrode located on the second active region is the same as a cross-sectional shape of a portion of the third gate electrode located on the third active region.
